(19) United States
(12) Patent Application Publication
(10) Pub. No.: US 2005/0259400 A1
(43) Pub. Date: Nov. 24, 2005

(54) Heat sinking structure of power semiconductor

(75) Inventor: Wen-Ping Huang, Taipei Hsien (TW)

Correspondence Address: BACON & THOMAS, PLLC, 625 SLATERS LANE, FOURTH FLOOR, ALEXANDRIA, VA, 22314, US

(73) Assignee: FORMOSA MICROSEMI CO., LTD., TAIPEI HSIEN (TW)

(21) Appl. No.: 10/851,055

(22) Filed: May 24, 2004

(51) Int. Cl. H05K 7/20

(52) U.S. Cl. 361/704

(57) ABSTRACT

The heat sinking structure of the present invention is fixedly provided on the surface of a crystal layer of a semiconductor with a heat conducting plate made of copper, the heat conducting plate has therein a plurality of channels parallel to the surface of the crystal layer, the channels extend through the heat conducting plate to form passageways for guiding air flow to exhaust, and to speed up the heat exchanging of the heat conducting plate with air, so that a heat sinking structure that is structurally firm, small by volume and high in efficiency of heat sinking as well as easy for processing in manufacturing is obtained.

### BACKGROUND OF THE INVENTION

1. Field of the Invention

The present invention is related to an improved heat sinking structure of a power semiconductor, and especially to a heat sinking structure which is structurally firm, small by volume and high in efficiency of heat sinking, and is easy for processing in manufacturing.

2. Description of the Prior Art

Traces of using power electrons can be seen in industry, household electric appliances, electric power systems, traffic, aviation, computer communication and military applications etc. Power semiconductor elements are often used to effect converting and control of the alternating and direct electric currents in the field of power electronic technique to satisfy various requirements. As shown in FIG. 1 depicting a schematic view of a conventional structure of power semiconductor, the entire structure basically takes a crystal layer 10 made of silicon (or germanium) as a main body; the crystal layer 10 is extended outwardly to be provided with necessary electrically-connecting pins 11, the electrically connecting pins 11 are used to make connection of the entire power semiconductor with electric circuits.

When high temperature is generated in practical operation of the power semiconductor, it affects the effect of operation of the power semiconductor; therefore, mostly a conventional power semiconductor element is fixedly provided on the surface of the crystal layer 10 with a heat conducting plate 20 made of copper, so that a user can add a heat sink 30 fully with fins 31 according to an electric circuit design, the fins 31 can increase the area of contacting of the heat source with air, and thus an object of lowering the temperature of the power semiconductor can be obtained.

However, the function of heat sinking of the conventional power semiconductor element is effected by adding the heat sink 30 on the heat conducting plate 20, hence the heat sink 30 and the heat conducting plate 20 must be firmly combined to avoid short circuit by dropping of the heat sink 30; and more, it has been a tendency that changing-over type electric power supplies shall be small by volume, low by density, high by efficiency and have the superiority of price competition capability; the power semiconductor elements in the electric power supplies similarly are developed toward the goal of making their volumes more minimized, this will make the work of adding heat sinks difficult, and will make the preciseness and the cost of production of the heat sinks added on the power semiconductors increased, and thereby the heat sinking structures of the power semiconductors added thereon with heat sinks will no more meet the requirement of being small by volume and low by density required for electric circuits.

### SUMMARY OF THE INVENTION

The heat sinking structure of a power semiconductor of the present invention mainly is provided on the surface of a crystal layer of the semiconductor with a heat conducting plate made of copper, the heat conducting plate has therein a plurality of channels parallel to the surface of the crystal layer of the semiconductor, the channels extend through the heat conducting plate to form passageways for guiding air flow to exhaust, and to speed up the heat exchanging of the heat conducting plate with air, so that a structure like a heat sink is formed on the heat conducting plate, this can increase the efficiency of heat sinking of the power semiconductor without making too large changing of the volume; and more, the heat conducting plate is fixedly provided on the surface of the crystal layer and will not have the worry of being loosened.

The present invention will be apparent in its structural combination and its entire mode of operation after reading the detailed description of the preferred embodiments thereof in reference to the accompanying drawings.

### BRIEF DESCRIPTION OF THE DRAWINGS

FIG. 1 is a schematic perspective view showing the heat sinking structure of a conventional power semiconductor;

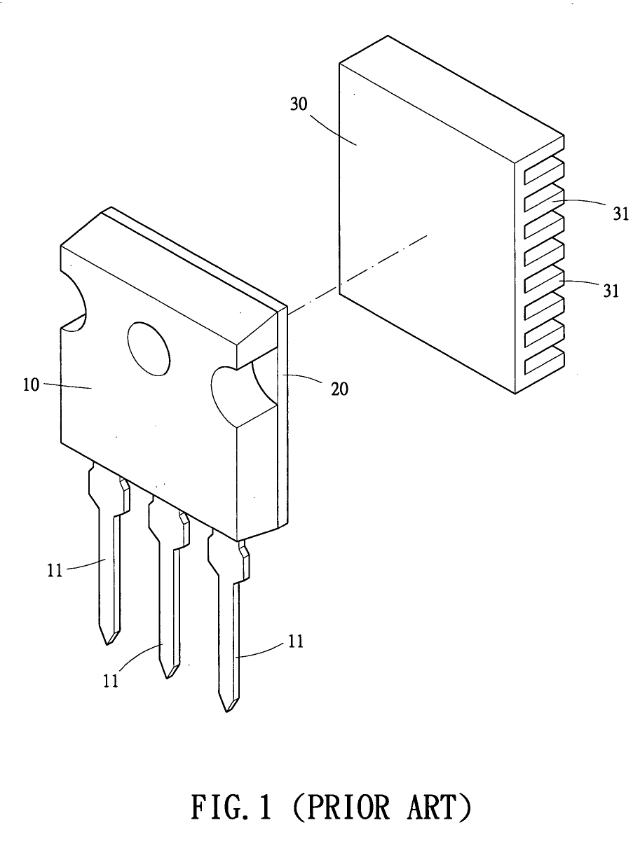

FIG. 2 is a perspective view showing the appearance of the heat sinking structure of a power semiconductor of a first embodiment of the present invention;

FIG. 3 is a perspective view of the heat sinking structure of the present invention in use;

FIG. 4 is a perspective view showing the appearance of the heat sinking structure of a power semiconductor of a second embodiment of the present invention;

FIG. 5 is a perspective view showing the appearance of the heat sinking structure of a power semiconductor of a third embodiment of the present invention;

FIG. 6 is a perspective view showing the appearance of the heat sinking structure of a power semiconductor of a fourth embodiment of the present invention;

FIG. 7 is a perspective view showing the appearance of the heat sinking structure of a power semiconductor of a fifth embodiment of the present invention.

### DETAILED DESCRIPTION OF THE PREFERRED EMBODIMENT

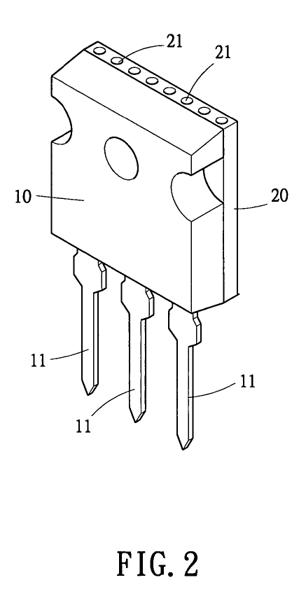

Referring to FIG. 2, the basic structure of the power semiconductor in the heat sinking structure of the power semiconductor of the present invention is as shown in FIG. 2, in the same way it takes a crystal layer 10 made of silicon (or germanium) as a main body; the crystal layer 10 is extended outwardly to be provided with necessary electrically-connecting pins 11, and is fixedly provided on the surface of the crystal layer 10 with a heat conducting plate 20 made of copper. Wherein the heat conducting plate 20 has therein a plurality of channels 21 parallel to the surface of the crystal layer 10 of the semiconductor; the channels 21 extend through the heat conducting plate 20 vertically or transversely, thereby the inner walls of the channels 21 are added with more contact areas with air and form passageways for guiding air flow to exhaust.

Consequently, a structure like a heat sink is formed on the heat conducting plate 20 to speed up exhausting of air of a heat source; plus continuous evolving/exhausting of the heat of a heat source generated by the crystal layer 10 by the heat transmitting action of the heat conducting plate 20 itself, a structure of heat exchanging with extremely good efficiency of heat sinking is formed. Particularly, the heat conducting plate 20 is directly and fixedly provided on the surface of the crystal layer 10, so that the heat conducting plate 20 having the channels 21 of predetermined specification can be manufactured in advance, and can be formed integrally with the power semiconductor when the latter is produced; this not only makes the cost of production lower but also renders none of the worry of being loosened of the heat conducting plate 20, and will not make too large changing of the volume of the power semiconductor, rather, this can more meet the requirement of making the volume of the power semiconductor more minimized.

Pins 11 of a conventional power semiconductor mostly are extended downwardly from the bottom of the crystal layer 10, and the power semiconductor is connected with an electric circuit in an upright state, and the channels 21 of the heat conducting plate 20 extend vertically, the channels 21 can be used as passageways for guiding air flow upwardly for ventilation by the vertical extending through of the channels 21, the physical phenomenon of flowing upwardly of the hot air forms an effect of chimney to further make speeding up of exhausting of the heat source and heat exchange of air.

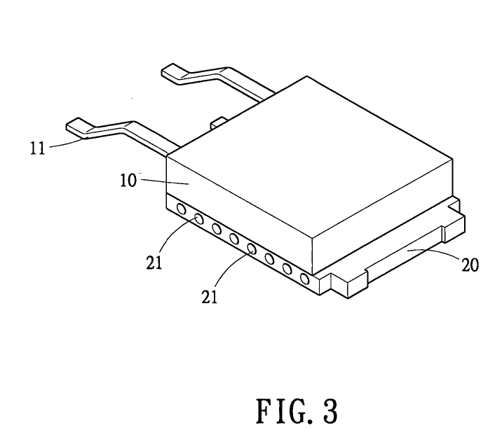

As shown in FIG. 3, pins 11 of some power semiconductor are extended transversely and then bent downwardly from a side of the crystal layer 10, thereby the power semiconductor is laid flat to connect with an electric circuit; the heat sinking structure of the present invention also suits such type of power semiconductor, this is because that the heat conducting plate 20 on the surface of the crystal layer 10 can similarly increases the area of contacting of the heat source with air and forms passageways for guiding air flow to exhaust.

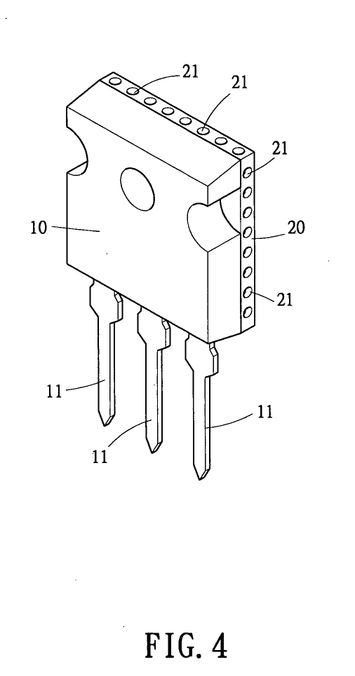

And more, the mode of arrangement of the channels 21 allocated on the heat conducting plate 20 of the present invention can be like that shown in FIG. 4, wherein the heat conducting plate 20 has a plurality of channels 21 arranged vertically, and has a plurality of channels 21 arranged transversely, such mode of arrangement of the channels 21 can increase the amount arranged of the channels 21, so that the area of contacting of the heat conducting plate 20 with air is increased to increase the space for ventilation and heat sinking of the air flow.

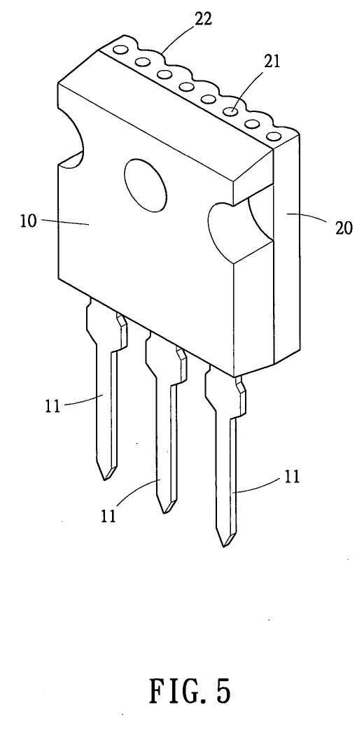

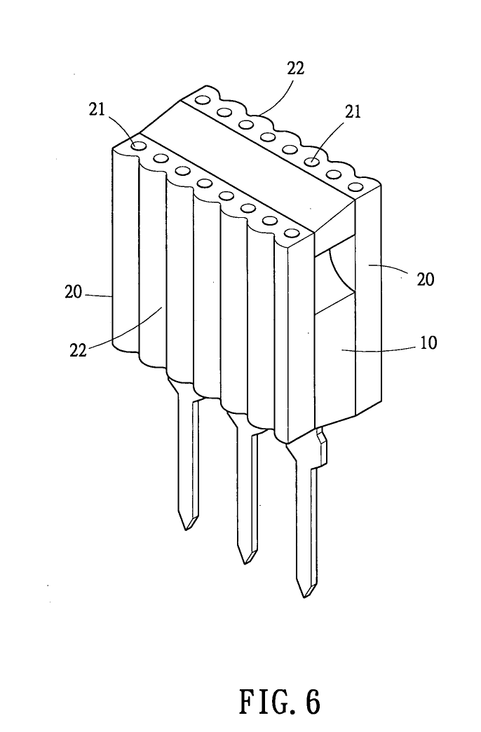

Moreover, as shown in FIG. 5, the structure of the power semiconductor of the present invention can be further provided on the surface of the heat conducting plate 20 with an undulated surface 22 that has a larger area than that of a conventional plane surface to thereby help exhausting of the hot source. Certainly, when in necessity, the entire heat sinking structure can also be fixedly provided on the two lateral sides (i.e., the front and the rear sides) of the crystal layer 10 with a heat conducting plate 20 having channels 21 and an undulated surface 22 such as is shown in FIG. 6, this can increase the effect of heat sinking of the power semiconductor.

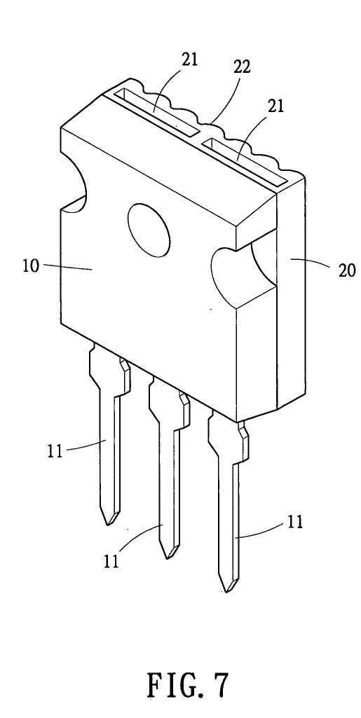

And as shown in FIG. 7, the above stated channels 21 of the heat conducting plate 20 is to be used as passageways for guiding air flow for ventilation, and can further make speeding up of generating air for exhausting of the heat source and heat exchange. By this reason, their shapes can be rectangular or square as depicted.

Although this invention has been disclosed and illustrated with reference to particular preferred embodiments, these are not for giving any limitation to the scope of the present invention. It will be apparent to those skilled in this art that various equivalent modifications or changes in structure, assembling and features without departing from the spirit of this invention shall also fall within the scope of the appended claims.

Having thus described the present invention providing a better practicable heat sinking structure for a power semiconductor as stated above, what I claim as new and desire to be secured by Letters Patent of the United States are:

1. A heat sinking structure of a power semiconductor, said power semiconductor is provided with electrically-connecting pins extending outwardly of a crystal layer, and is fixedly provided on a surface of said crystal layer with a heat conducting plate; said structure is characterized by that:
said heat conducting plate has therein a plurality of channels parallel to said surface of said crystal layer, said channels extend through said heat conducting plate to form passageways for guiding air flow to exhaust, thereby said heat sinking structure is formed and suits minimized power semiconductors.

2. The heat sinking structure of a power semiconductor as in claim 1, wherein said channels of said heat conducting plate extend vertically to be arranged at constant intervals.

3. The heat sinking structure of a power semiconductor as in claim 1, wherein said channels of said heat conducting plate extend vertically and transversely to be arranged at constant intervals.

4. The heat sinking structure of a power semiconductor as in claim 1, wherein said heat conducting plate has an undulated surface.

5. The heat sinking structure of a power semiconductor as in claim 1, wherein said crystal layer is provided on each of two lateral sides thereof with a heat conducting plate.
